(19) United States
(12) Patent Application Publication
(10) Pub. No.: US 2004/0001539 A1
(43) Pub. Date: Jan. 1, 2004

(54) Training using overhead data in a wireless communications network

(76) Inventors: Sundar G. Sankaran, San Jose, CA (US); Paul Petrus, Santa Clara, CA (US); Mitchell D. Trott, Mountain View, CA (US); John S. Chen, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/180,867

(22) Filed: Jun. 26, 2002

(51) Int. Cl. H03K 5/159; H03H 7/30

(52) U.S. Cl. 375/231; 375/350

(57) ABSTRACT

The present invention can be used to perform training using secondary data. In one embodiment the present invention includes receiving a communications signal of a communications channel, where the communications signal has a primary and a secondary data segment both communicating information, and determining a parameter of the communications channel using the secondary data segment. In another embodiment of the present invention, the communications signal can also include a training segment containing a known training signal.

### BACKGROUND OF THE INVENTION

1. Field of the Invention

The present invention applies to the field of wireless communications systems and, in particular, to using overhead data for training.

2. Description of the Prior Art

Mobile radio communications systems such as cellular voice and data radio systems typically have several base stations in different locations available for use by mobile or fixed user terminals, such as cellular telephones or wireless web devices. Each base station communicates with a user terminal using a communications channel. For example, a communications channel may consist of a time slot in a TDMA (Time Division Multiple Access) frame on a physical carrier frequency. A TDMA frame may contain, for example, three downlink transmit time slots followed by three uplink receive time slots. The time slots may be used to transmit communication bursts, or they may be delineated on a continuous signal. A communications burst is a signal with a definite beginning and end. Thus, each time slot may contain a burst.

A physical carrier frequency may be a 200 kHz band around a central frequency, such as 800 MHz or 1.9 GHz. Thus, a base station transmits to a given user terminal, for example, on the second transmit and receive time slots on this carrier frequency in a given frame. Furthermore, the communications channel may be organized using common duplexing techniques, such as FDD (Frequency Division Duplex), TDD (Time Division Duplex), and common multiple access techniques such as FDMA (Frequency Division Multiple Access), and CDMA (Code Division Multiple Access). The channel may further be organized according to a hopping function indicating alternating resources.

The communications channel is used for sending signals that communicate information. This information may be user data or control data. The control data may be in a secondary data segment of the signals, such as a FACCH segment. Typically this control data includes information that enables communication of the primary user data, such as power control, channel allocation, and other non-user data. The communications channel may also be used for sending signals that do not communicate information, but are completely known at the receiver. Such signals are known as training or pilot signals. Training signal can be generated in many ways, such as sending a known symbol sequence, typically called a training sequence. In the description below, the terms training signal and training sequence are sometimes used interchangeably.

Training signals can be used for measuring channel parameters and characteristics, such as SNR (signal to noise ratio), spatial parameters, timing, and frequency offset. They can also be used for synchronization, calibration, or the calculation of spatial and temporal filter weights. Training sequences are useful because the received signal can be compared with the known sent signal, e.g., the known training sequence. Training generally means performing some operation including comparing a received signal to a reference signal. Thus, all the above uses of training signals and training sequences are training. Since training sequences and training signals contain no information, they are overhead that reduces the efficiency of the communications network.

### BRIEF SUMMARY OF THE INVENTION

The present invention can be used to perform training using secondary data. In one embodiment the present invention includes receiving a communications signal of a communications channel, where the communications signal has a primary and a secondary data segment both communicating information, and determining a parameter of the communications channel using the secondary data segment. In another embodiment of the present invention, the communications signal can also include a training segment containing a known training signal.

### BRIEF DESCRIPTION OF THE DRAWINGS

The present invention is illustrated by way of example, and not by way of limitation, in the figures of the accompanying drawings in which like reference numerals refer to similar elements and in which:

FIG. 1 is a flow chart of training using a secondary data segment according to one embodiment of the present invention.

FIG. 2 is a flow chart of training using a FACCH according to another embodiment of the present invention.

FIG. 3 is a flow chart of training using a FACCH according to another embodiment of the present invention.

FIG. 4 is a simplified block diagram of a base station on which an embodiment of the invention can be implemented; and

FIG. 5 is a simplified block diagram of a remote terminal on which an embodiment of the invention can be implemented.

### DETAILED DESCRIPTION OF THE INVENTION

According to one embodiment of the invention, a FACCH, TFCI, or similar control data sequence can be used to determine phase, gain, filter weights, or spatial parameters of a received signal. The FACCH can be used as a training sequence, or in addition to the training sequence. The FACCH and the training sequence can be used together to estimate the phase or other parameters of the payload of the received signal.

Training Using Secondary Data Segments

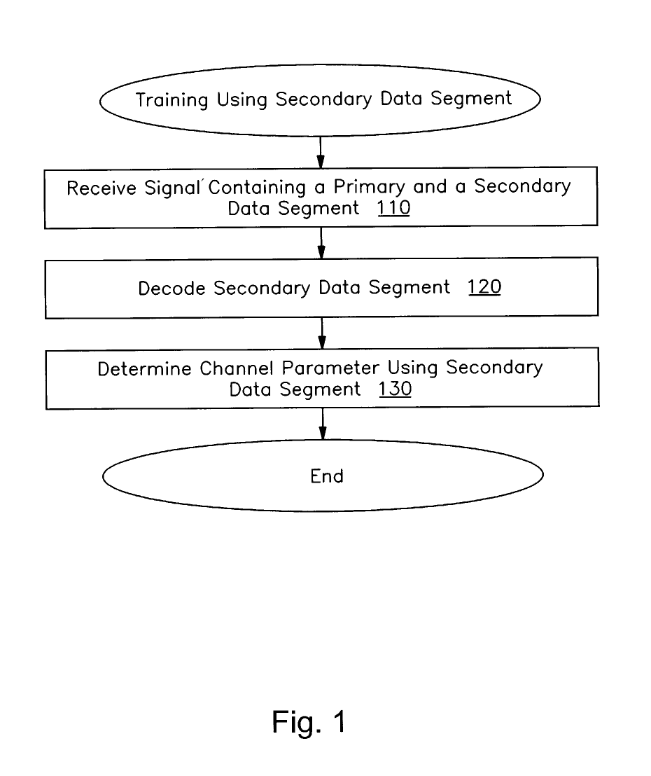

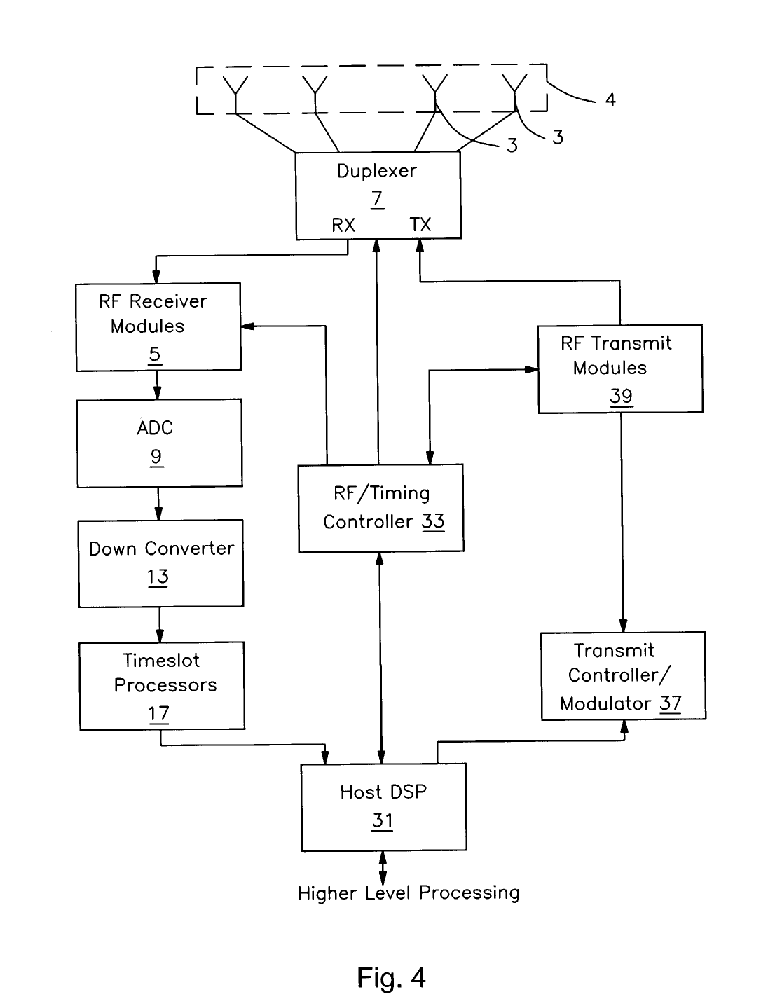

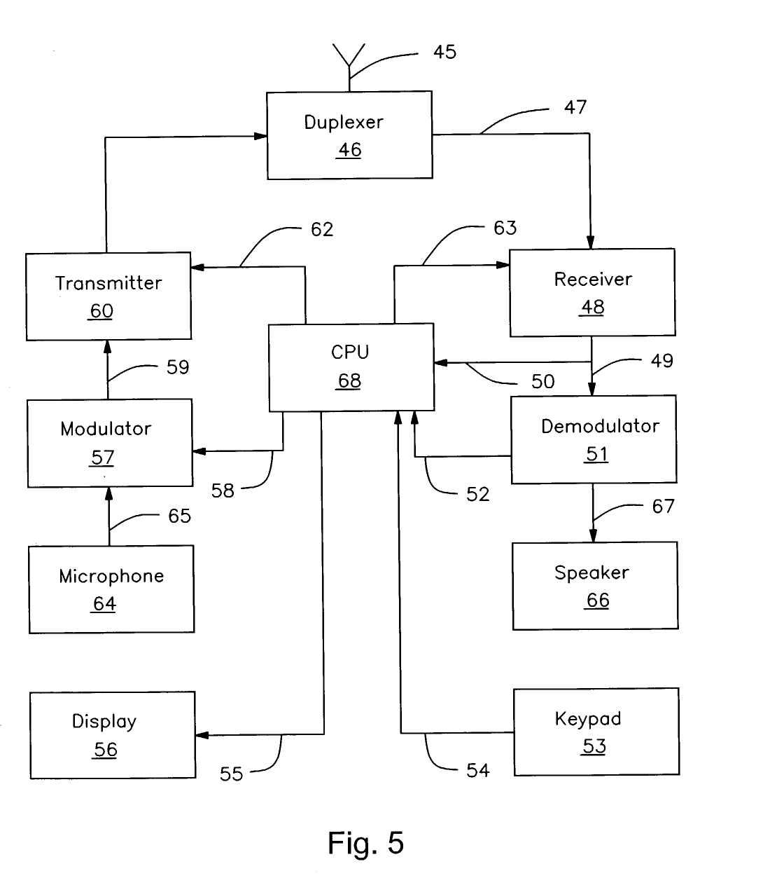

One embodiment of the present invention can be understood with reference to FIG. 1. FIG. 1 provides a flow chart of training using a secondary data segment. First, a signal is received 110 at a receiver, such as the receiver 48 in FIG. 5 or the receiver modules 5 in FIG. 4, on a communications channel. In one embodiment, the signal is a burst. The signal includes a primary data segment and a secondary data segment. The primary data segment may be used to carry user data. In one embodiment, the secondary data segment is used to carry control information, such as power control information, modulation class information about the primary data segment, SINR (Signal to Interference and Noise Ratio) reports, channel allocation commands, and buffer status reports.

Different systems use different terminology to describe secondary data segments. For example, in the GSM (Global System for Mobile Communications) protocol, among others, the secondary data segment is referred to as the FACCH (Fast Associated Control Channel. In W-CDMA (Wideband-CDMA), it is called the TFCI (Transport Format Combination Indicator). Other protocols and standards may have other names for the secondary data segment. The secondary data segment need not have any distinguishing features over the primary data segment, and may be used to carry any type of data, including user data. However, the secondary data segment generally uses the same modulation format over time, and is used to carry control information. The secondary data segment may be in a consistent location in signals, time-slots, or bursts or it may be indicated by flag bits or other indicators.

After the signal is received, the secondary data segment is decoded 120, resulting in the secondary data being extracted. In one embodiment, the secondary data differs from a training sequence in that it is used to communicate information, such as modulation class information about the primary segment, or other control information, as explained above. In contrast, a training sequence is completely known at the receiver. In one embodiment, the secondary data also differs from user data in that it is used only to communicate certain information, such as power control information. In contrast, user data may generally be used to communicate any information. Thus, while the secondary data is not completely known at the receiver, it may be more predictable than user data. The secondary data may also be more predictable, for example, due to modulation format. If the modulation format used to encode the secondary data segment uses fewer symbols, or constellation points, than the modulation format used to encode the primary data segment, the secondary data segment becomes more predictable than the primary data segment.

In one embodiment of the present invention, the secondary data segment is encoded using a Walsh-Hadamard code. Since the Walsh-Hadamard code is a non-coherent modulation format, i.e., no phase reference is needed for decoding, no training sequence is required to decode the secondary data segment. In such an embodiment, the received signal need not include a training sequence. However, if the received signal does include a training sequence, the secondary data segment can still be used for additional training. Alternately, the secondary data segment may be encoded using a coherent modulation format. In this case, the received signal may include some training, enough to decode the secondary data segment. Then, the secondary data segment can be used for any additional training required to decode the primary data segment, according to one embodiment of the present invention.

In one embodiment of the invention, the secondary data segment, since it only carries certain information, is known at the receiver to contain one of a finite number of codewords, a codeword being a bit or symbol sequence. Thus, even if some symbols are not detected correctly, the correct codeword can be identified by finding the codeword in the set of possible codewords closest to the received secondary data segment. In one embodiment, this is the codeword with the highest correlation with the received and demodulated secondary data segment.

After the secondary data segment is decoded, it can be used to determine 130 a channel parameter, such as spatial parameters, timing, and phase parameters like frequency offset, i.e., for training. This training may be done by comparing the received codeword with the decoded codeword, or the received signal with the estimated sent signal, i.e., a reference signal. The secondary data segment can be used as a training sequence because, similar to a training sequence, the receiver knows both the received signal, or sequence of symbols, and the transmitted signal, or sequence of symbols. Once the channel parameter is determined, it may be used to decode the primary data segment.

Determining Frequency Offset Using a FACCH

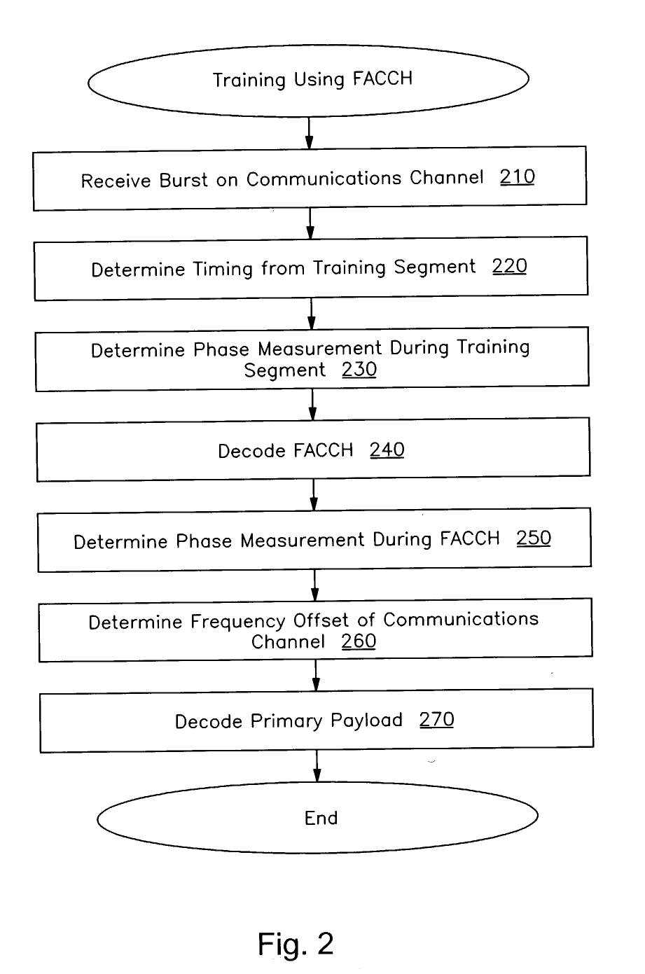

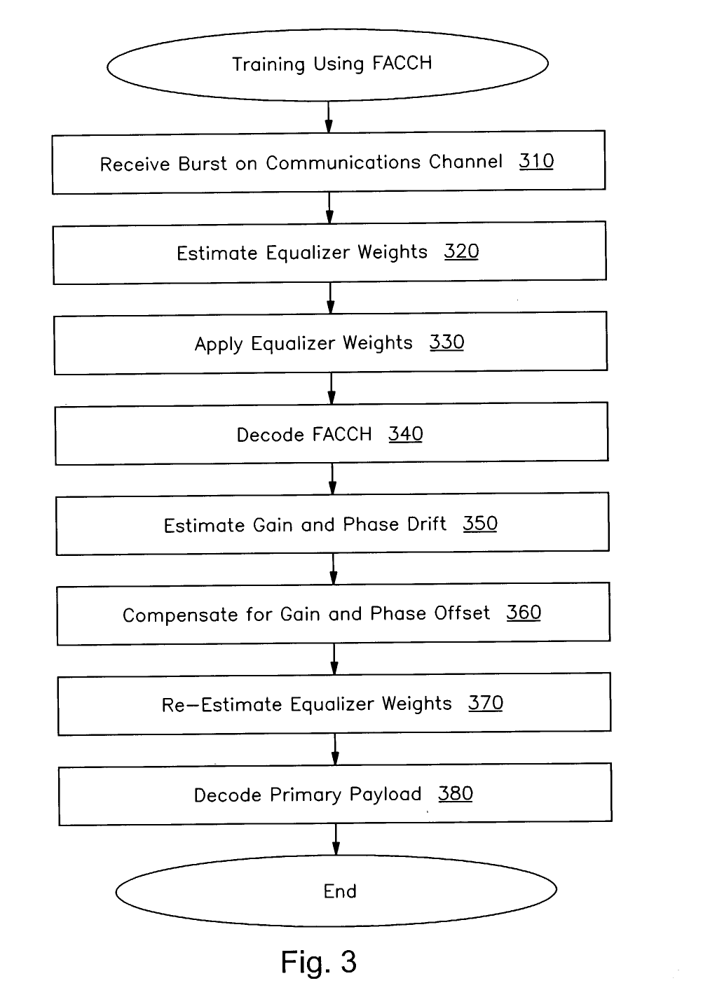

One embodiment of the present invention is now described with reference to FIG. 2. FIG. 2 provides a flow chart of determining frequency offset during a burst using a FACCH. This embodiment of the present invention is described in the context of a system using bursts, where the secondary data segment, i.e., the FACCH, is used to determine frequency offset. In this example, the FACCH is used by a base station receiver, such as receiver modules 5 in FIG. 3, to determine the frequency offset on an uplink burst. As described above, the invention is not limited by these specific details.

First, a burst is received 210 at a receiver of the base station from a user terminal, such as the device of FIG. 5, on a communications channel. Table 1 illustrates the content of one example of a received burst.

TABLE 1

| NAME | DURATION | LENGTH |
|---|---|---|
| Ramp-Up | 10 μs | 5 symbols |
| Training | 114 μs | 57 symbols |
| Primary Payload | 364 μs | 182 symbols |
| FACCH Payload | 32 μs | 16 symbols |
| Ramp-down | 10 μs | 5 symbols |
| Guard | 15 μs | |

The training segment of 114 μs includes a known training sequence of 57 symbols. This sequence is completely known at the receiver and thus communicates no information. This sequence may be any sequence of symbols, but will generally have some desirable qualities. Various uses of the training sequence are set forth above.

The primary payload segment of 364 μs includes 182 symbols of user data. The amount of information bits in the burst depends on the modulation format used to encode the user data. The user data, or primary data, is the information communicated by the end users. This may include voice data, visual data, text data, or any other kind of information. Generally, transmitting the primary user data is the reason for using the communications network.

The FACCH payload segment of 32 μs includes the 16 symbols of secondary data. The secondary data, or FACCH data, is control data, such as modulation class, power control, and other secondary information, as explained above. The burst also includes Ramp-Up, Ramp-Down, and Guard segments.

After the burst shown above is received, the known training sequence transmitted during the training segment is used to determine 220 the timing on the communications channel. This may be done, for example, by generating a reference signal using the known training sequence, correlating the received signal with copies of the oversampled reference signal with different time-lags, and taking the time-lag corresponding with largest correlation as the timing. The training sequence is also used to determine 230 a phase measurement, such as the phase of the communications channel during the training segment. This may be done, for example, by correlating the baud-aligned, i.e., timing-corrected, received signal with the reference signal.

In one embodiment, the FACCH is encoded using a robust modulation scheme, such as a 16-ary Walsh-Hadamard code, but the primary data segment has a varying modulation format that may change. That is, the modulation scheme used to encode the primary payload containing the user data can vary from burst to burst. The modulation format to be used in a particular burst may be dependent on the quality of the communications channel at the time the burst is encoded. The channel quality may be determined using the SINR, or some other channel quality parameter. Thus, to decode the primary data segment, the receiver is informed of the modulation scheme used to encode the primary data segment. In one embodiment, the FACCH, or some portion of the FACCH, carries modulation class information about the primary segment. In one embodiment, there are sixteen possible Walsh-Hadamard codewords possible for the FACCH. Thus, the primary data segment may be encoded using one of sixteen modulation formats. Alternately, the primary data segment may be encoded using one of only eight, or any number less than sixteen, modulation formats, and the excess information capacity may be used to communicate other information, such as power control.

After the phase is determined from the training sequence, the FACCH payload is decoded 240. In one embodiment, the FACCH is decoded using a Walsh-Hadamard decoder. For example, a decoder may apply a FHT (Fast Hadamard Transform) to correlate each possible Walsh-Hadamard codeword with the received FACCH payload. Then, the codeword with the largest correlation may be designated as the decoded FACCH payload. Other codewords and decoders can also be designed. The designed set of codewords may have good auto-correlation and cross-correlations properties to allow for easier detection at low signal to noise ratios. Once the received and decoded FACCH payload are both known, the decoded FACCH payload is used as a training sequence to determine 250 a phase measurement, such as the phase of the communications channel during the FACCH segment.

Since, in this embodiment, the primary payload is located between the training segment and the FACCH payload, the two determined phases can be used to determine the phase ramp for the received burst. The phase ramp represents the frequency offset of the communications channel during the burst, so the phase measurements are used to determine 260 the frequency offset. One way of determining the phase ramp is to assume that the phase varies continuously between the phase measurement at the training sequence in the beginning of the burst and the phase measurement at the FACCH at the end of the burst. Using this assumption, the phase ramp through the primary payload can be calculated by linear interpolation between the two phase measurements. In alternate embodiments, other methods may be used to determine the phase ramp, such as non-linear interpolation, averaging, and various other statistical devices. In alternate embodiments in which a burst contains primary payload not located between a training and a FACCH segment, the phase ramp may be calculated by other means, such as extrapolation.

Then, the primary payload is decoded 270. To decode the primary payload, the determined timing is applied to the received burst to compensate for the timing of the channel and the radio. Then, the frequency offset is removed by offsetting the phase of the received burst by the determined phase ramp for the burst. The decoder then uses the modulation format indicated by the decoded FACCH payload to extract the user data bits from the primary payload.

In portions of the description above, the burst was described with reference to Table 1. However, in alternate embodiments the received burst may not include a training segment at all. In these embodiments, all necessary training is performed using the FACCH, or other secondary data segment. In these embodiments, the FACCH may be modulated in a manner that can be demodulated without training. In one embodiment, the received burst contains two or more separate FACCH segments, any number of which may be used for training or in place of a training sequence in another capacity. If the training segment is eliminated, the training symbols may be used to transmit user data or any other data. The eliminated training, symbols may be placed into the primary payload, left out entirely, used for a FACCH or for any other purpose.

Furthermore, in portions of the description above, the secondary data segment used for training was a described as a FACCH. However, as explained above, any secondary data segment may be used for training according to embodiments of the present invention. A secondary data segment differs from other data segments in that, at least in part, the secondary data segment includes data that is predictable, but not completely known. The secondary data being predictable means that at least portions of the secondary data, for example the first eight symbols, can only contain a certain number of sequences, as opposed to any possible symbol sequence.

For example, if there are two possible symbols, as in a BPSK modulation format, for example, the total number of possible sequences for the 16 symbols of the secondary data segment is 2¹⁶=65536. If, for example, only 16 possible symbol sequences, i.e., codewords, can occupy the 16 symbol positions of the secondary segment, the content of those 16 symbols becomes predictable. For example, if the received symbol sequence in the 16 symbol positions does not match any allowed codeword, but would match one codeword if one symbol was altered and another codeword if 3 symbols were altered, the codeword originally sent was more likely the first than the second. Thus, the secondary data segment is predictable. In one embodiment, the secondary data segment is used only to communicate control data. In another embodiment, only portions of the secondary data segment, such as the first eight symbol positions, are predictable.

Estimating Equalizer Weights Using a FACCH

One embodiment of the present invention is now described with reference to FIG. 3. FIG. 3 provides a flow chart of estimating equalizer weights for a downlink burst using a FACCH. This embodiment of the present invention is described in the context of a system using bursts, where the secondary data segment, i.e., the FACCH, is used to estimate equalizer weights. In this example, the FACCH is used by a user terminal receiver, such as receiver 48 in FIG. 5, to estimate equalizer weights on a downlink burst. As described above, the invention is not limited by these specific details.

First, a burst is received 310 at a receiver of the user terminal from a base station, such as the device of FIG. 4, on a communications channel. Table 2 illustrates the content of one example of a received burst.

TABLE 2

| NAME | DURATION | LENGTH |
|---|---|---|
| Training #1 | 68 μs | 34 symbols |
| FACCH Payload | 32 μs | 16 symbols |
| Primary Payload | 920 μs | 460 symbols |
| Training #2 | 36 μs | 18 symbols |

The first training segment, Training #1, of 68 μs includes a known training sequence of 34 symbols. This sequence is completely known at the receiver and thus communicates no information. This sequence may be any sequence of symbols, but will generally have some desirable qualities. Various example uses of this training segment are set forth above.

The FACCH Payload segment of 32 μs includes the 16 symbols of secondary data. The secondary data, or FACCH data, is control data, such as modulation class of the Primary Payload, power control, and other secondary information, as explained above.

The second training segment, Training #2, of 36 μs includes a known training sequence of 18 symbols. This sequence, like the first training sequence, is completely known at the receiver and thus communicates no information. This sequence may also be any sequence of symbols, but will generally be selected to have some desirable qualities.

The Primary Payload segment of 920 μs includes 460 symbols of user data. The amount of information bits in the burst depends on the modulation format used to encode the user data. The user data, or primary data, is the information communicated by the end users. This may include voice data, visual data, text data, or any other kind of information. Generally, transmitting the primary user data is the reason for using the communications network. The received burst also includes Ramp-Up, Ramp-Down, and Guard segments that are not illustrated in Table 2.

After the burst is received, it is used by the receiver to estimate 320 a first set of equalizer weights. In one embodiment, only the first training segment, Training #1, is used to estimate the first set of equalizer weights. The equalizer may be a temporal filter that compensates for delay spread and other channel imperfections. In one embodiment, the equalizer is a least-squares based equalizer, and the equalizer weights are estimated by minimizing a least-squares cost function, with the solution being given by Equation 1:

w=R_{zz}⁻¹R_{zs}; (1)

where R_{zs} is the cross correlation vector between the received signal z and the reference signal s, and R_{zz}⁻¹ is the inverse of the temporal correlation matrix of the received signal z. In this embodiment, the resulting weights are represented by complex vector w.

Once the first set of equalizer weights are estimated, they are applied 330 by the receiver to the received burst. In one embodiment, the estimated first set of equalizer weights are only applied to the training and FACCH segments of the received burst. Next, the FACCH is decoded 340. In one embodiment, this is done in the manner described with reference to FIG. 2 above.

After the FACCH is decoded, the gain and phase drift across the burst is estimated 350. In one embodiment, the gain and phase drift is estimated using the two training segments. In another embodiment, the FACCH may be used in addition to the two training segments. The FACCH may be used for training after being decoded as described with reference to FIGS. 1 and 2 above. The phase drift is the frequency offset, or phase ramp, as described above, and the gain drift is the amplitude variation across the burst. In one embodiment, the gain and phase drift is estimated by interpolating between the gain and the phase at the beginning of the burst, as calculated using the first training segment, and the gain and phase at the end of the burst, as calculated using the second training segment. The gain and phase can be estimated by using a known training segment to generate a reference signal s, and calculating:

θ=z's/z'z;

where:

z is the received signal,

'is the complex conjugate transpose, i.e., Hermitian operator, and

/is the complex division operator.

The result, θ is a complex number. The magnitude of θ represents the gain and the angle of θ in the complex plane represents the phase of the communications channel and the radio. Then, the estimated gain and phase drift is applied 360 to the burst to compensate for the gain and frequency offset. In one embodiment, the estimated gain and phase is only applied to the first training segment, Training #1, and the FACCH payload.

After the gain and phase offset is compensated for, the equalizer weights are re-estimated 370. In one embodiment, the new set of equalizer weights are estimated using the first training segment and the FACCH. In embodiments using downlink bursts as shown in Table 2, the first training segment and the FACCH are adjacent, together forming a longer training sequence. The new set of equalizer weights can be calculated using the least-squares method of Equation 1. The reference signal is generated using both the first training segment and the FACCH payload and the received signal is taken over the first training segment and the FACCH payload. The new set of equalizer weights resulting from the re-estimation may be more accurate than the first set of equalizer weights, because the signal used has been compensated for gain and phase offset, and is longer because it includes the FACCH payload.

After the equalizer weights have been re-estimated, the Primary Payload is decoded 380. Decoding the Primary Payload can include compensating for gain and frequency offset during the Primary Payload and applying the equalizer with the new set of re-estimated weights to the Primary Payload, as discussed above. Then, the symbols can be interpreted and the user data extracted according to the modulation format used, which may be known at the receiver prior to the burst being received or which may be included in the FACCH Payload.

Base Station Structure

The present invention relates to wireless communication systems and may be a fixed-access or mobile-access wireless network using spatial division multiple access (SDMA) technology in combination with multiple access systems, such as time division multiple access (TDMA), frequency division multiple access (FDMA) and code division multiple access (CDMA). Multiple access can be combined with frequency division duplexing (FDD) or time division duplexing (TDD). FIG. 4 shows an example of a base station of a wireless communications system or network suitable for implementing the present invention. The system or network includes a number of subscriber stations, also referred to as remote terminals or user terminals, such as that shown in FIG. 5. The base station may be connected to a wide area network (WAN) through its host DSP 31 for providing any required data services and connections external to the immediate wireless system. To support spatial diversity, a plurality of antennas 3 is used, for example four antennas, although other numbers of antennas may be selected.

A set of spatial multiplexing weights for each subscriber station are applied to the respective modulated signals to produce spatially multiplexed signals to be transmitted by the bank of four antennas. The host DSP 31 produces and maintains spatial signatures for each subscriber station for each conventional channel and calculates spatial multiplexing and demultiplexing weights using received signal measurements. In this manner, the signals from the current active subscriber stations, some of which may be active on the same conventional channel, are separated and interference and noise suppressed. When communicating from the base station to the subscriber stations, an optimized multi-lobe antenna radiation pattern tailored to the current active subscriber station connections and interference situation is created. Suitable smart antenna technologies for achieving such a spatially directed beam are described, for example, in U.S. Pat. Nos. 5,828,658, issued Oct. 27, 1998 to Ottersten et al. and 5,642,353, issued Jun. 24, 1997 to Roy, III et al. The channels used may be partitioned in any manner. In one embodiment the channels used may be partitioned as defined in the GSM (Global System for Mobile Communications) air interface, or any other time division air interface protocol, such as Digital Cellular, PCS (Personal Communication System), PHS (Personal Handyphone System) or WLL (Wireless Local Loop). Alternatively, continuous analog or CDMA channels can be used.

The outputs of the antennas are connected to a duplexer switch 7, which in a TDD embodiment, may be a time switch. Two possible implementations of the duplexer switch are as a frequency duplexer in a frequency division duplex (FDD) system, and as a time switch in a time division duplex (TDD) system. When receiving, the antenna outputs are connected via the duplexer switch to a receiver 5, and are converted down in analog by RF receiver (“RX”) modules 5 from the carrier frequency to an FM intermediate frequency (“IF”). This signal then is digitized (sampled) by analog to digital converters (“ADCs”) 9. Final down-converting to baseband is carried out digitally. Digital filters can be used to implement the down-converting and the digital filtering, the latter using finite impulse response (FIR) filtering techniques. This is shown as block 13. The invention can be adapted to suit a wide variety of RF and IF carrier frequencies and bands.

There are, in the present example, eight down-converted outputs from each antenna's digital filter 13, one per receive timeslot. The particular number of timeslots can be varied to suit network needs. While GSM uses eight uplink and eight downlink timeslots for each TDMA frame, desirable results can also be achieved with any number of TDMA timeslots for the uplink and downlink in each frame. For each of the eight receive timeslots, the four down-converted outputs from the four antennas are fed to a digital signal processor (DSP) 17 (hereinafter “timeslot processor”) for further processing, including calibration, according to one aspect of this invention. Eight Motorola DSP56300 Family DSPs can be used as timeslot processors, one per receive timeslot. The timeslot processors 17 monitor the received signal power and estimate the frequency offset and time alignment. They also determine smart antenna weights for each antenna element. These are used in the SDMA scheme to determine a signal from a particular remote user and to demodulate the determined signal.

The output of the timeslot processors 17 is demodulated burst data for each of the eight receive timeslots. This data is sent to the host DSP processor 31 whose main function is to control all elements of the system and interface with the higher level processing, which is the processing which deals with what signals are required for communications in all the different control and service communication channels defined in the system's communication protocol. The host DSP 31 can be a Motorola DSP56300 Family DSP. In addition, timeslot processors send the determined receive weights for each user terminal to the host DSP 31. The host DSP 31 maintains state and timing information, receives uplink burst data from the timeslot processors 17, and programs the timeslot processors 17. In addition it decrypts, descrambles, checks error correcting code, and deconstructs bursts of the uplink signals, then formats the uplink signals to be sent for higher level processing in other parts of the base station. Furthermore DSP 31 may include a memory element to store data, instructions, or hopping functions or sequences. Alternatively, the base station may have a separate memory element or have access to an auxiliary memory element. With respect to the other parts of the base station it formats service data and traffic data for further higher processing in the base station, receives downlink messages and traffic data from the other parts of the base station, processes the downlink bursts and formats and sends the downlink bursts to a transmit controller/modulator, shown as 37. The host DSP also manages programming of other components of the base station including the transmit controller/modulator 37 and the RF timing controller shown as 33.

The RF timing controller 33 interfaces with the RF system, shown as block 45 and also produces a number of timing signals that are used by both the RF system and the modem. The RF controller 33 reads and transmits power monitoring and control values, controls the duplexer 7 and receives timing parameters and other settings for each burst from the host DSP 31.

The transmit controller/modulator 37, receives transmit data from the host DSP 31. The transmit controller uses this data to produce analog IF outputs which are sent to the RF transmitter (TX) modules 35. Specifically, the received data bits are converted into a complex modulated signal, up-converted to an IF frequency, sampled, multiplied by transmit weights obtained from host DSP 31, and converted via digital to analog converters (“DACs”) which are part of transmit controller/modulator 37 to analog transmit waveforms. The analog waveforms are sent to the transmit modules 35. The transmit modules 35 up-convert the signals to the transmission frequency and amplify the signals. The amplified transmission signal outputs are sent to antennas 3 via the duplexer/time switch 7.

User Terminal Structure

FIG. 5 depicts an example component arrangement in a remote terminal that provides data or voice communication. The remote terminal's antenna 45 is connected to a duplexer 46 to permit the antenna 45 to be used for both transmission and reception. The antenna can be omni-directional or directional. For optimal performance, the antenna can be made up of multiple elements and employ spatial processing as discussed above for the base station. In an alternate embodiment, separate receive and transmit antennas are used eliminating the need for the duplexer 46. In another alternate embodiment, where time division duplexing is used, a transmit/receive (TR) switch can be used instead of a duplexer as is well known in the art. The duplexer output 47 serves as input to a receiver 48. The receiver 48 produces a down-converted signal 49, which is the input to a demodulator 51. A demodulated received sound or voice signal 67 is input to a speaker 66.

The remote terminal has a corresponding transmit chain in which data or voice to be transmitted is modulated in a modulator 57. The modulated signal to be transmitted 59, output by the modulator 57, is up-converted and amplified by a transmitter 60, producing a transmitter output signal 61. The transmitter output 61 is then input to the duplexer 46 for transmission by the antenna 45.

The demodulated received data 52 is supplied to a remote terminal central processing unit 68 (CPU) as is received data before demodulation 50. The remote terminal CPU 68 can be implemented with a standard DSP (digital signal processor) device such as a Motorola series 56300 Family DSP. This DSP can also perform the functions of the demodulator 51 and the modulator 57. The remote terminal CPU 68 controls the receiver through line 63, the transmitter through line 62, the demodulator through line 52 and the modulator through line 58. It also communicates with a keyboard 53 through line 54 and a display 56 through line 55. A microphone 64 and speaker 66 are connected through the modulator 57 and the demodulator 51 through lines 65 and 66, respectively for a voice communications remote terminal. In another embodiment, the microphone and speaker are also in direct communication with the CPU to provide voice or data communications. Furthermore remote terminal CPU 68 may also include a memory element to store data, instructions, and hopping functions or sequences. Alternatively, the remote terminal may have a separate memory element or have access to an auxiliary memory element.

In one embodiment, the speaker 66, and the microphone 64 are replaced or augmented by digital interfaces well-known in the art that allow data to be transmitted to and from an external data processing device (for example, a computer). In one embodiment, the remote terminal's CPU is coupled to a standard digital interface such as a PCMCIA interface to an external computer and the display, keyboard, microphone and speaker are a part of the external computer. The remote terminal's CPU 68 communicates with these components through the digital interface and the external computer's controller. For data only communications, the microphone and speaker can be deleted. For voice only communications, the keyboard and display can be deleted.

General Matters

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

The present invention includes various steps. The steps of the present invention may be performed by hardware components, such as those shown in FIGS. 4 and 5, or may be embodied in machine-executable instructions, which may be used to cause a general-purpose or special-purpose processor or logic circuits programmed with the instructions to perform the steps. Alternatively, the steps may be performed by a combination of hardware and software. The steps have been described as being performed by either the base station or the user terminal. However, many of the steps described as being performed by the base station may be performed by the user terminal and vice versa. Furthermore, the invention is equally applicable to systems in which terminals communicate with each other without either one being designated as a base station, a user terminal, a remote terminal or a subscriber station. Thus, the present invention is equally applicable and useful in a peer-to-peer wireless network of communications devices using frequency hopping and spatial processing. These devices may be cellular phones, PDA's, laptop computers, or any other wireless devices.

In portions of the description above, the received burst was received at the base station. In other embodiment described above, the user terminal received the burst. Thus, embodiments of the present invention may be used on the uplink or the downlink by either a base station or a user terminal, or any other communications device that is not designated as either, as, for example, in a Peer to Peer system. Furthermore, the received burst or signal is sometimes described as including both a training segment and a secondary data segment, such as a FACCH. However, embodiments of the invention may be practiced without any training included in the received burst or signal. In these embodiments, the secondary data segment may be encoded using a non-coherent modulation format. However, in other embodiments, the secondary data segment may be encoded using coherent modulation formats.

Furthermore, in portions of the description above, the FACCH is shown at the end of the received burst. In other portions, the FACCH is shown adjacent to a training segment. However, embodiments of the present invention can have the FACCH be in the beginning, middle, or end of the burst, or scattered throughout the burst in smaller pieces. Alternately, the FACCH, or secondary data segment, need not be separated by time from the primary payload. For example, in an embodiment using CDMA, the primary payload may be included on the quadrature channel, while the secondary data segment may be included on the inphase channel, separated by code.

Also, in portions of the description above, the secondary data segment is used to train a receiver by calculating various channel parameters. In other portions, the secondary data segment is used to train an equalizer. However, embodiments of the present invention may be used for any training ordinarily performed using a training sequence. For example, embodiments of the present invention may be used for packet, network, or phase and symbol synchronization, or for filter weight calculations.

The present invention may be provided as a computer program product, which may include a machine-readable medium having stored thereon instructions, which may be used to program a computer (or other electronic devices) to perform a process according to the present invention. The machine-readable medium may include, but is not limited to, floppy diskettes, optical disks, CD-ROMs, and magneto-optical disks, ROMs, RAMs, EPROMs, EEPROMs, magnet or optical cards, flash memory, or other type of media/machine-readable medium suitable for storing electronic instructions. Moreover, the present invention may also be downloaded as a computer program product, wherein the program may be transferred from a remote computer to a requesting computer by way of data signals embodied in a carrier wave or other propagation medium via a communication link (e.g., a modem or network connection).

Many of the methods are described in their most basic form, but steps can be added to or deleted from any of the methods and information can be added or subtracted from any of the described messages without departing from the basic scope of the present invention. It will be apparent to those skilled in the art that many further modifications and adaptations can be made. The particular embodiments are not provided to limit the invention but to illustrate it. The scope of the present invention is not to be determined by the specific examples provided above but only by the claims below.

It should also be appreciated that reference throughout this specification to “one embodiment” or “an embodiment” means that a particular feature may be included in the practice of the invention. Similarly, it should be appreciated that in the foregoing description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

What is claimed is:

1. A method comprising:
receiving a burst on a communications channel, the burst comprising a first training segment containing a first known training sequence, which precedes a secondary data segment containing one of a set of codewords representing control data, which precedes a primary data segment containing user data, which precedes a second training segment containing a second known training sequence;
estimating a first set of equalizer weights using, at least one of, the first training segment and the second training segment;
compensating for a channel imperfection of the communications channel by applying the estimated first set of equalizer weights to, at least, the first training segment, the secondary data segment, and the second training segment;
extracting the control data by decoding the secondary data segment to determine a codeword from the set of codewords contained therein;
estimating a gain and phase of the communications channel during the burst using, at least, the first training segment and the second training segment;
compensating for a gain and phase offset across, at least, the first training segment and the secondary data segment, using the estimated gain and phase;
estimating a second set of equalizer weights using, at least, the first training segment and the secondary data segment; and
decoding the primary data segment using the estimated gain and phase and the estimated second set of equalizer weights.

2. The method of claim 1, wherein estimating the first set of equalizer weights comprises minimizing a least-squares cost function.

3. The method of claim 1, wherein the channel imperfection comprises a timing offset of the communications channel.

4. The method of claim 1, wherein extracting the control data comprises:
comparing the secondary data segment to the set of codewords; and
selecting a codeword from the set of codewords based on the comparison.

5. The method of claim 4, wherein the secondary data segment is encoded using a non-coherent modulation format.

6. The method of claim 5, wherein the secondary data segment is encoded using a Walsh-Hadamard code.

7. The method of claim 6, wherein comparing comprises correlating the secondary data segment with the set of codewords by performing a Fast Hadamard Transform (FHT) on the secondary data segment and the codewords in the set.

8. The method of claim 7, wherein selecting comprises selecting the codeword from the set that has a maximum absolute value as a result of the FHT.

9. The method of claim 4, wherein comparing comprises correlating the secondary data segment with the set of codewords.

10. The method of claim 1, wherein estimating the gain and phase comprises:
determining a gain and phase measurement during the first training segment;
determining a gain and phase measurement during the second training segment; and
determining the gain and phase across the burst by interpolating between the gain and phase measurement during the first training segment and the gain and phase measurement during the second training segment.

11. The method of claim 1, wherein estimating the second set of equalizer weights comprises minimizing a least-squares cost function.

12. The method of claim 1, wherein decoding the primary data segment comprises:
compensating for the gain and phase across the primary data segment;
applying the second set of equalizer weights to the primary data segment; and
extracting the user data contained in the primary data segment.

13. The method of claim 12, wherein extracting the user data comprises applying a modulation format indicated by the extracted control data to the primary data segment.

14. The method of claim 1, wherein the secondary data segment comprises a FACCH (Fast Associated Control Channel).

15. A method comprising:
receiving a burst on a communications channel, the burst comprising a training segment containing a first known training sequence, which precedes a primary data segment containing user data, which precedes a secondary data segment containing one of a set of codewords representing control data;
determining a timing offset of the communications channel using the training segment;
determining a gain and phase of the communications channel across the training segment;
extracting the control data by decoding the secondary data segment to determine a codeword from the set of codewords contained therein;
determining a gain and phase of the communications channel across the secondary data segment; and
decoding the primary data segment using the determined timing offset, the determined gain and phase across the training segment and the determined gain and phase across the secondary data segment.

16. The method of claim 15, wherein extracting the control data by decoding the secondary data segment to determine the codeword from the set of codewords contained therein comprises:
comparing the secondary data segment to the set of codewords; and
selecting a codeword from the set of codewords based on the comparison.

17. The method of 16, wherein the secondary data segment is encoded using a non-coherent modulation format.

18. The method of claim 17, wherein the secondary data segment is encoded using a Walsh-Hadamard code.

19. The method of claim 18, wherein comparing comprises correlating the secondary data segment with the set of codewords by performing a Fast Hadamard Transform (FHT) on the secondary data segment and the codewords in the set.

20. The method of claim 19, wherein selecting the codeword comprises selecting the codeword from the set that has a maximum absolute value as a result of the FHT.

21. The method of claim 16, wherein comparing the secondary data segment to the set of codewords comprises correlating the secondary data segment with the set of codewords.

22. The method of claim 15, wherein decoding the primary data segment comprises:
compensating for the determined timing offset across the primary data segment;
determining the gain and phase across the primary data segment by interpolating between the determined gain and phase across the training segment and the determined gain and phase across the secondary data segment;
compensating for the determined gain and phase across the primary data segment; and
extracting the user data contained in the primary data segment.

23. The method of claim 22, wherein extracting the user data comprises applying a modulation format indicated by the extracted control data to the primary data segment.

24. The method of claim 15, wherein the secondary data-segment comprises a FACCH (Fast Associated Control Channel).

25. A method comprising:
receiving a communications signal on a communications channel, the signal comprising a primary data segment and a secondary data segment, wherein the primary and secondary data segments contain data used to communicate information; and
determining a parameter of the communications channel using the secondary data segment.

26. The method of claim 25, further comprising extracting primary information by decoding the data contained in the primary data segment using the determined parameter.

27. The method of claim 26, further comprising:
extracting secondary information, wherein extracting the secondary information comprises decoding the data contained in the secondary data segment; and wherein
extracting the primary information comprises extracting the primary information using the extracted secondary information.

28. The method of claim 27, wherein the secondary information comprises information about a modulation format used to encode the primary data segment, and the primary information comprises user data communicated on the communications channel.

29. The method of claim 25, wherein the parameter comprises a phase parameter of the communications channel.

30. The method of claim 29, wherein the phase parameter comprises a frequency offset of the communications channel.

31. The method of claim 25, wherein the parameter comprises a timing offset of the communications channel.

32. The method of claim 25, wherein the parameter comprises an impulse response of the communications channel.

33. The method of claim 25, wherein the parameter comprises a spatial processing parameter to be used on the communications channel.

34. The method of claim 25, wherein the parameter comprises a gain and phase of the communications channel.

35. The method of claim 25, wherein the secondary data segment comprises a FACCH (Fast Associated Control Channel).

36. The method of claim 25, wherein the signal comprises a burst.

37. The method of claim 25, wherein determining the parameter comprises:
comparing the secondary data segment to a set of expected codewords;
selecting a codeword from the set of expected codewords based on the comparison; and
determining the parameter of the communications channel by comparing the secondary data segment to the selected codeword.

38. The method of claim 37, wherein the secondary data segment is encoded using a non-coherent modulation format.

39. The method of claim 38, wherein the secondary data segment is encoded using a Walsh-Hadamard code.

40. The method of claim 39, wherein comparing the secondary data comprises correlating the secondary data segment with the set of expected codewords by performing a Fast Hadamard Transform (FHT) on the secondary data segment and each expected codeword in the set.

41. The method of claim 40, wherein selecting the codeword comprises selecting the codeword from the set that has a maximum absolute value as a result of the FHT.

42. The method of claim 37, wherein comparing the secondary data segment comprises correlating the secondary data segment with the set of expected codewords.

43. The method of claim 25, wherein the received signal further comprises a training segment, wherein the training segment contains a known training sequence, and wherein the primary data segment is located between the training segment and the secondary data segment in the received signal.

44. The method of claim 43, further comprising:
determining the parameter of the communications channel using the training segment; and
determining the parameter of the communications channel during the primary segment using the parameter determined using the training segment and the parameter determined using the secondary data segment.

45. The method of claim 44, wherein determining the parameter of the communications channel during the primary segment comprises interpolating between the parameter determined using the training segment and the parameter determined using the secondary data segment.

46. A communication burst carrying modulated data, the data comprising:
a first training segment containing a first known training sequence;
a secondary data segment containing control data;
a primary data segment containing user data; and
a second training segment containing a second known training sequence; wherein
the first training segment precedes the secondary data segment, which precedes the primary data segment, which precedes the second training segment.

47. The burst of claim 46, wherein the control data is represented by one of a set of codewords.

48. The burst of claim 47, wherein the set of codewords comprises a set of Walsh-Hadamard codewords.

49. The burst of claim 47, wherein the set of codewords have a maximum cross-correlation below a threshold.

50. The burst of claim 47, wherein the set of codewords have a maximum auto-correlation for non-zero lag below a threshold.

51. A communication burst carrying modulated data, the data comprising:
a training segment containing a first known training sequence;
a primary data segment containing user data; and
a secondary data segment containing control data; wherein
the training segment precedes the primary data segment, which precedes the secondary data segment.

52. The burst of claim 51, wherein the control data is represented by one of a set of codewords.

53. The burst of claim 52, wherein the set of codewords comprises a set of Walsh-Hadamard codewords.

54. The burst of claim 52, wherein the set of codewords have a maximum cross-correlation below a threshold.

55. The burst of claim 52, wherein the set of codewords have a maximum auto-correlation for non-zero lag below a threshold.

56. A communication burst carrying modulated data, the data comprising:
a training segment containing a known training sequence;
a secondary data segment containing control data; and
a primary data segment containing user data; wherein the primary data segment is between the training segment and the secondary data segment.

57. The burst of claim 56, further comprising a second training segment containing a second known training sequence, wherein the second training segment is adjacent to the secondary data segment.

58. A communications device comprising:
a receiver to receive a communications signal on a communications channel, the signal comprising a primary data segment and a secondary data segment, wherein the primary and secondary data segments contain data used to communicate information; and
a processor to determine a parameter of the communications channel using the secondary data segment of the received communications signal.

59. The communications device of claim 58, wherein the processor extracts primary information by decoding the data contained in the primary data segment using the determined parameter.

60. The communications device of claim 59, wherein the processor further:
extracts secondary information by decoding the data contained in the secondary data segment, and uses the extracted secondary information to extract the primary information.

61. The communications device of claim 60, wherein the secondary information comprises information about a modulation format used to encode the primary data segment, and the primary information comprises user data communicated on the communications channel.

62. The communications device of claim 58, wherein the parameter comprises a phase parameter of the communications channel.

63. The communications device of claim 62, wherein the phase parameter comprises a frequency offset of the communications channel.

64. The communications device of claim 58, wherein the parameter comprises a timing offset of the communications channel.

65. The communications device of claim 58, wherein the parameter comprises an impulse response of the communications channel.

66. The communications device of claim 58, wherein the parameter comprises a spatial processing parameter to be used on the communications channel.

67. The communications device of claim 58, wherein the parameter comprises a gain and phase of the communications channel.

68. The communications device of claim 58, wherein the secondary data segment comprises a FACCH (Fast Associated Control Channel).

69. The communications device of claim 58, wherein the signal comprises a burst.

70. The communications device of claim 58, wherein the processor determines the parameter by:
comparing the secondary data segment to a set of expected codewords;
selecting a codeword from the set of expected codewords based on the comparison; and
comparing the secondary data segment to the selected codeword.

71. The communications device of claim 70, wherein the secondary data segment is encoded using a non-coherent modulation format.

72. The communications device of claim 71, wherein the secondary data segment is encoded using a Walsh-Hadamard code.

73. The communications device of claim 72, wherein the processor further comprises a Fast Hadamard Transform Module to compare the secondary data segment to the set of expected codewords by correlating the secondary data segment with the set of expected codewords by performing a Fast Hadamard Transform (FHT) on the secondary data segment and each expected codeword in the set.

74. The communications device of claim 73, wherein the processor selects the codeword from the set of expected codewords by selecting the codeword that has a maximum absolute value as a result of the FHT.

75. The communications device of claim 70, wherein the processor compares the secondary data segment to the set of expected codewords by correlating the secondary data segment with the set of expected codewords.

76. The communications device of claim 58, wherein the received signal further comprises a training segment, wherein the training segment contains a known training sequence, and wherein the primary data segment is located between the training segment and the secondary data segment in the received signal.

77. The communications device of claim 76, wherein the processor further:
determines the parameter of the communications channel using the training segment; and
determines the parameter of the communications channel during the primary segment using the parameter determined using the training segment and the parameter determined using the secondary data segment.

78. The communications device of claim 77, wherein the processor determines the parameter of the communications channel during the primary segment by interpolating between the parameter determined using the training segment and the parameter determined using the secondary data segment.

79. A machine-readable medium having stored thereon data representing instructions that, when executed by a processor, cause the processor to perform operations comprising:
receiving a communications signal on a communications channel, the signal comprising a primary data segment and a secondary data segment, wherein the primary and secondary data segments contain data used to communicate information; and
determining a parameter of the communications channel using the secondary data segment.

80. The machine-readable medium of claim 58, wherein the instructions further cause the processor to perform operations comprising extracting primary information by decoding the data contained in the primary data segment using the determined parameter.

81. The machine-readable medium of claim 59, wherein the instructions further cause the processor to perform operations comprising:
extracting secondary information by decoding the data contained in the secondary data segment; and wherein
extracting the primary information further uses the extracted secondary information.

82. The machine-readable medium of claim 81, wherein the secondary information comprises information about a modulation format used to encode the primary data segment, and the primary information comprises user data communicated on the communications channel.

83. The machine-readable medium of claim 79, wherein the parameter comprises a phase parameter of the communications channel.

84. The machine-readable medium of claim 83, wherein the phase parameter comprises a frequency offset of the communications channel.

85. The machine-readable medium of claim 79, wherein the parameter comprises a timing offset of the communications channel.

86. The machine-readable medium of claim 79, wherein the parameter comprises an impulse response of the communications channel.

87. The machine-readable medium of claim 79, wherein the parameter comprises a spatial processing parameter to be used on the communications channel.

88. The machine-readable medium of claim 79, wherein the parameter comprises a gain and phase of the communications channel.

89. The machine-readable medium of claim 79, wherein the secondary data segment comprises a FACCH (Fast Associated Control Channel).

90. The machine-readable medium of claim 79, wherein the signal comprises a burst.

91. The machine-readable medium of claim 79, wherein determining the parameter of the communications channel using the secondary data segment comprises:
comparing the secondary data segment to a set of expected codewords;
selecting a codeword from the set of expected codewords based on the comparison; and
determining the parameter of the communications channel by comparing the secondary data segment to the selected codeword.

92. The machine-readable medium of claim 91, wherein the secondary data segment is encoded using a non-coherent modulation format.

93. The machine-readable medium of claim 92, wherein the secondary data segment is encoded using a Walsh-Hadamard code.

94. The machine-readable medium of claim 93, wherein comparing the secondary data segment to the set of expected codewords comprises correlating the secondary data segment with the set of expected codewords by performing a Fast Hadamard Transform (FHT) on the secondary data segment and each expected codeword in the set.

95. The machine-readable medium of claim 94, wherein selecting the codeword from the set of expected codewords comprises selecting the codeword from the set that has a maximum absolute value as a result of the FHT.

96. The machine-readable medium of claim 91, wherein comparing the secondary data segment to the set of expected codewords comprises correlating the secondary data segment with the set of expected codewords.

97. The machine-readable medium of claim 79, wherein the received signal further comprises a training segment, wherein the training segment contains a known training sequence, and wherein the primary data segment is located between the training segment and the secondary data segment in the received signal.

98. The machine-readable medium of claim 97, wherein the instructions further cause the processor to perform operations comprising:
determining the parameter of the communications channel using the training segment; and
determining the parameter of the communications channel during the primary segment using the parameter determined using the training segment and the parameter determined using the secondary data segment.

99. The machine-readable medium of claim 98, wherein determining the parameter of the communications channel during the primary segment comprises interpolating between the parameter determined using the training segment and the parameter determined using the secondary data segment.
